(19) United States
(12) Patent Application Publication
(10) Pub. No.: US 2023/0282273 A1
(43) Pub. Date: Sep. 7, 2023

(54) SEMICONDUCTOR DEVICE

(71) Applicant: RENESAS ELECTRONICS CORPORATION, Tokyo (JP)

(72) Inventors: Shinji TANAKA, Tokyo (JP); Daiki KITAGATA, Tokyo (JP)

(21) Appl. No.: 18/169,455

(22) Filed: Feb. 15, 2023

(30) Foreign Application Priority Data
Mar. 4, 2022 (JP) 2022-033699

(51) Int. Cl. G11C 11/417; G11C 11/412

(52) U.S. Cl. CPC G11C 11/417; G11C 11/412; G06F 7/5443

(57) ABSTRACT

In the semiconductor device according to an embodiment, a memory cell is controlled such that, for the part whose output value can be fixed based on the value stored in the memory cell without performing the information processing, the operation processing is stopped so as to stop the charging and discharging to and from the data line, and for the part whose output value needs to be fixed by performing the information processing, the information processing accompanied by charging and discharging to and from the data line is appropriately performed.

### CROSS-REFERENCE TO RELATED APPLICATIONS

The disclosure of Japanese Patent Application No. 2022-033699 filed on Mar. 4, 2022 including the specification, drawings and abstract is incorporated herein by reference in its entirety.

### BACKGROUND

The present invention relates to a semiconductor device, for example, a semiconductor device including a memory having a product-sum operation function.

In recent years, artificial intelligence has been used in many fields. This artificial intelligence needs to perform a large amount of product-sum operations. Therefore, a GPU (Graphics Processing Unit) or the like is used to accelerate the processing of the product-sum operation. Further, in addition to the processing of the product-sum operation, a large amount of data transfer processing is also required in association with the processing. In the case of performing such processing, there is a problem of the increase in the power consumption. Therefore, Patent Document 1 discloses a technique related to a semiconductor device capable of performing a large amount of product-sum operations with low power consumption.

There is disclosed a technique listed below.

[Patent Document 1] Japanese Unexamined Patent Application Publication No. 2020-129582

Patent Document 1 discloses a product operation memory cell that is connected to two data lines, stores ternary data, and performs product-sum operation of the stored data, input data, and data on the data lines.

### SUMMARY

However, in the semiconductor device described in Patent Document 1, charging and discharging to and from the data line are repeated in all the information processing cycles regardless of the types of operation. Therefore, the semiconductor device described in Patent Document 1 has the problem that the effect of reducing the power consumption is limited.

The other problems and novel features will become apparent from the description of this specification and accompanying drawings.

In the semiconductor device according to an embodiment, the memory cell is controlled such that, for the part whose output value can be fixed based on the value stored in the memory cell without performing the information processing, the operation processing is stopped so as to stop the charging and discharging to and from the data line, and for the part whose output value needs to be fixed by performing the information processing, the information processing accompanied by charging and discharging to and from the data line is appropriately performed.

In the semiconductor device according to the embodiment, it is possible to further reduce the power consumption.

### BRIEF DESCRIPTION OF THE DRAWINGS

FIG. 1 is a block diagram of a semiconductor device according to the first embodiment.

FIG. 2 is a detailed block diagram showing a configuration around memory cells of the semiconductor device according to the first embodiment.

FIG. 3 is a circuit diagram of an information processing reference cell according to the first embodiment.

FIG. 4 is a circuit diagram of the memory cell according to the first embodiment.

FIG. 5 is a circuit diagram of a replica cell and dummy cells according to the first embodiment.

FIG. 6 is a circuit diagram of a first determination circuit according to the first embodiment.

FIG. 7 is a circuit diagram of a second determination circuit according to the first embodiment.

FIG. 8 is a table for describing a relationship between a set value and the number of information processing cycles to be stopped in the semiconductor device according to the first embodiment.

FIG. 9 is a timing chart for describing the operation of the semiconductor device according to the first embodiment.

FIG. 10 is a table for describing changing conditions of the set value in a semiconductor device according to the second embodiment.

FIG. 11 is a detailed block diagram showing a configuration around memory cells of a semiconductor device according to the third embodiment.

FIG. 12 is a circuit diagram of a second determination circuit according to the third embodiment.

FIG. 13 is a detailed block diagram showing a configuration around memory cells of a semiconductor device according to the fourth embodiment.

FIG. 14 is a circuit diagram of a first partial determination circuit according to the fourth embodiment.

FIG. 15 is a circuit diagram of a second partial determination circuit according to the fourth embodiment.

### DETAILED DESCRIPTION

In order to clarify the description, the following description and drawings are omitted and simplified as appropriate. Also, in each drawing, the same elements are denoted by the same reference characters and the repetitive description thereof will be omitted as needed.

A semiconductor device described below has a configuration in which a plurality of memory cells capable of holding ternary values is connected to a data line provided in common to the plurality of memory cells. Then, the product-sum operation is performed by adding the products of the input value to the memory cell and the value stored in the memory cell on the data line. Further, the result of the product-sum operation is successively compared with the reference value output by the information processing reference cell, and is finally output as a multi-bit output value. Such a semiconductor device will be described in detail below.

### First Embodiment

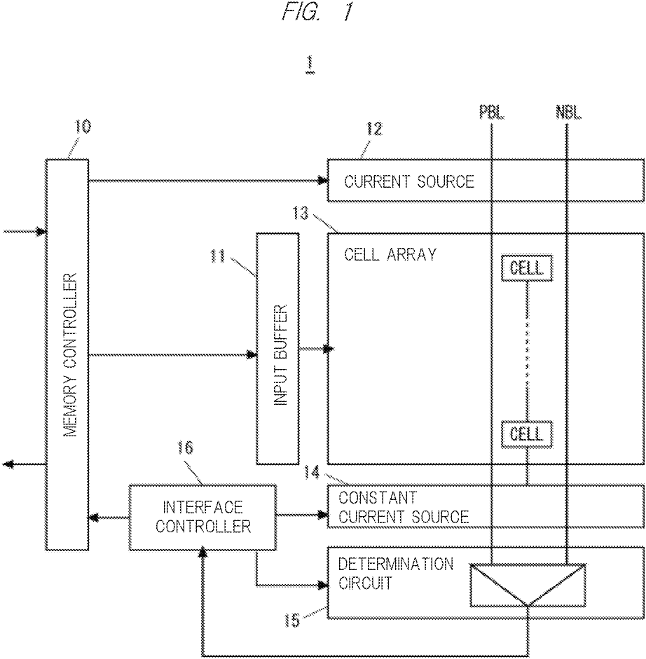

First, FIG. 1 shows a block diagram of a semiconductor device according to the first embodiment. As shown in FIG. 1, the semiconductor device 1 according to the first embodiment includes a memory controller 10, an input buffer 11, a current source 12, a cell array 13, a constant current source 14, a determination circuit 15, and an interface controller 16.

The memory controller 10 is an external interface with the semiconductor device 1, receives input values from a semiconductor device provided outside, and outputs output values generated within the semiconductor device 1 to the external device. Also, the memory controller 10 may have a function of controlling the power supply in the semiconductor device 1 such as the current source 12. The input buffer 11 drives the memory cells provided in the cell array 13 by converting an input value input via the memory controller 10 into a signal for controlling the memory cells.

The current source 12 generates currents to be supplied to a first data line (hereinafter, referred to as data line PBL), a second data line (hereinafter, referred to as data line NBL), and a third data line (hereinafter, referred to as data line DBL) of the cell array 13. The cell array 13 has memory cells arranged in a grid pattern. The constant current source 14 generates a constant current that drives the memory cells in the cell array 13. The determination circuit 15 determines the magnitude of the results of the product-sum operation from the memory cells in the cell array 13, and sequentially outputs the bit constituting the final output value bit by bit. The interface controller 16, for example, generates a multi-bit final output value from the output value of the determination circuit 15 and transmits it to the memory controller 10. Further, the interface controller 16 functions also as a control circuit that controls the constant current source 14 and the determination circuit 15 based on the determination signal output by the determination circuit 15.

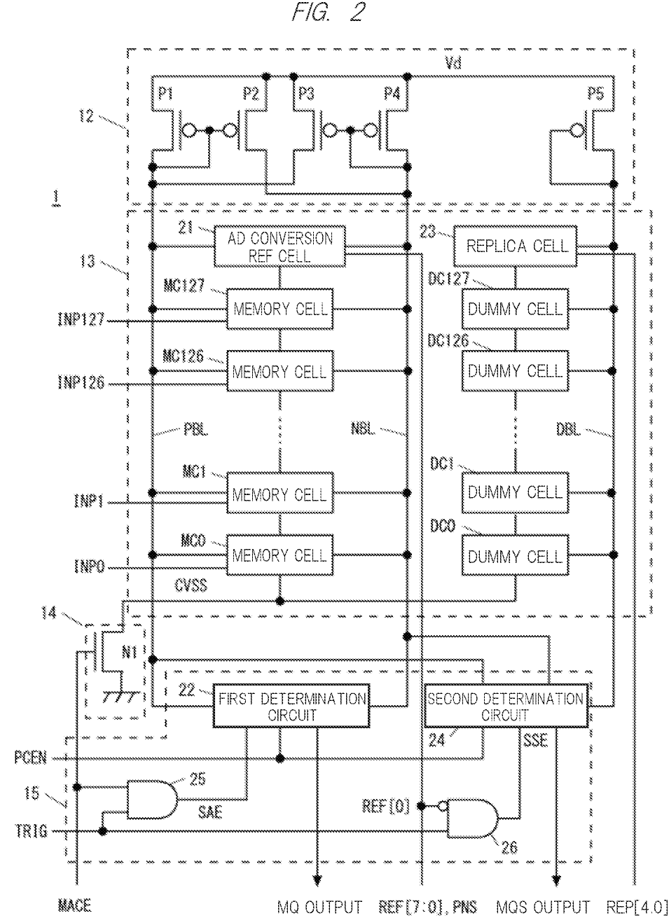

The following description focuses on the configurations of the current source 12, the cell array 13, the constant current source 14, and the determination circuit 15. Thus, FIG. 2 shows a detailed block diagram of a configuration around the memory cells of the semiconductor device according to the first embodiment. In FIG. 2, the data line PBL, the data line NBL, and the data line DBL constitute one data line group, and the circuit related to one data line group is shown. In the semiconductor device 1 according to the first embodiment, the cell array 13 is provided with the data line groups, and a plurality of the current sources 12, the constant current sources 14, the determination circuits 15, and others associated with the data line groups.

As shown in FIG. 2, in the semiconductor device 1 according to the first embodiment, a plurality of memory cells (for example, MC0 to MC127) is provided so as to be connected to the data lines PBL and NBL. An input value supplied to the memory cells is configured of multiple bits, but a corresponding one bit of the input value is input to each memory cell. Then, the memory cell outputs the product of the 1-bit input value and the held value represented by a ternary value. Although details will be described later, the memory cell includes a first memory cell that electrically connects the data line PBL to the constant current source 14 when the first value is held and a second memory cell that electrically connects the data line NBL to the constant current source 14 when the second value is held. Namely, the memory cells that output the first value among the plurality of memory cells are electrically connected to the data line PBL. Also, the memory cells that output the second value among the plurality of memory cells are electrically connected to the data line NBL.

Further, an information processing reference cell (for example, AD conversion REF cell 21) is provided so as to be connected to the data lines PBL and NBL. The AD conversion REF cell 21 supplies a reference value, which changes for each information processing cycle, to either the data line PBL or the data line NBL. The AD conversion REF cell 21 changes the reference value according to the reference control signal REF. Also, it is assumed that the interface controller 16 outputs the reference control signal REF.

A replica cell 23 and a plurality of dummy cells (for example, dummy cells DC0 to DC127) are connected to the data line DBL. The cell array 13 outputs a comparison value, which indicates the number of memory cells connected to at least one of the data line PBL and the data line NBL, to the data line DBL in accordance with a specified set value (for example, set value REP). The dummy cell spuriously produces the parasitic capacitance that the memory cell supplies to the data line PBL or the data line NBL.

The current source 12 has PMOS transistors P1 to P5. The PMOS transistor P1 has a source connected to a power supply wiring Vd, a gate and a drain connected commonly, and the drain connected to the data line PBL. The PMOS transistor P2 has a gate connected in common with the gate of the PMOS transistor P1, a source connected to the power supply wiring Vd, and a drain connected to the data line NBL. The PMOS transistor P3 has a gate connected in common with a gate of the PMOS transistor P4, a source connected to the power supply wiring Vd, and a drain connected to the data line PBL. The PMOS transistor P4 has a source connected to the power supply wiring Vd, the gate and a drain connected commonly, and the drain connected to the data line NBL. The PMOS transistor P5 has a drain connected to the data line DBL.

Namely, in the semiconductor device 1, the total current of a current generated by the diode-connected PMOS transistors that supply a current to one of the data lines PBL and NBL and a current generated by the diode-connected PMOS transistors that supply a current to the other of the data lines PBL and NBL is caused to flow. In this way, in the semiconductor device 1, by using the current source 12, variations in current supplied to the data lines PBL and NBL are reduced. In the example shown in FIG. 2, current only from the PMOS transistor P5 is supplied to the data line DBL.

The constant current source 14 has an NMOS transistor N1. The NMOS transistor N1 has a source grounded, a gate supplied with a product-sum operation mode enable signal MACE, and a drain connected to a cell ground wiring CVSS. The cell ground wiring CVSS is connected to the plurality of memory cells, the AD conversion REF cells 21, the plurality of dummy cells, and the replica cell 23. Then, the constant current source 14 generates drive currents, with which the plurality of memory cells and the AD conversion REF cells 21 drive the data lines PBL and NBL, via the cell ground wiring CVSS. Also, the constant current source 14 generates a drive current with which the replica cell 23 drives the data line DBL. Note that the constant current source 14 supplies a ground voltage to the plurality of dummy cells. Also, it is assumed that the interface controller 16 outputs the product-sum operation mode enable signal MACE supplied to the constant current source 14.

The determination circuit 15 has a first determination circuit 22, a second determination circuit 24, an AND gate 25, and an AND gate 26 with inverting input. The first determination circuit 22 outputs a binary signal, which indicates a different value in accordance with the magnitude relationship between the number of memory cells connected to the data line PBL and the number of memory cells connected to the data line NBL, for each information processing cycle. The second determination circuit 24 enables a stop command signal MQS when at least one of the number of memory cells connected to the data line PBL and the number of memory cells connected to the data line NBL is smaller than a comparison value (value determined based on a voltage generated on the data line DBL).

The product-sum operation mode enable signal MACE is input to one input of the AND gate 25, and a trigger signal TRIG is input to the other input of the AND gate 25. The AND gate 25 supplies the result of logical AND operation of the product-sum operation mode enable signal MACE and the trigger signal TRIG to the first determination circuit 22 as a sense amplifier enable signal SAE. The least significant bit of the reference control signal REF is input to an inverting input terminal of the AND gate 26 with inverting input, and the trigger signal TRIG is input to a non-inverting input terminal of the AND gate 26 with inverting input. Also, the AND gate 26 with inverting input supplies the trigger signal TRIG, which is input during the period in which the least significant bit of the reference control signal REF is 0, to the second determination circuit 24 as a second sense enable signal SSE.

A power supply control enable signal PCEN and the sense amplifier enable signal SAE are input to the first determination circuit 22 as control signals. The first determination circuit 22 operates during the period in which both the power supply control enable signal PCEN and the sense amplifier enable signal SAE are in an enable state (for example, high level). The power supply control enable signal PCEN and the second sense enable signal SSE are input to the second determination circuit 24 as control signals. The second determination circuit 24 operates during the period in which the power supply control enable signal PCEN and the second sense enable signal SSE are in the enable state.

Next, an example of a specific circuit for the circuit block shown in FIG. 2 will be described. Note that each circuit block can be realized even in the circuit other than that shown below.

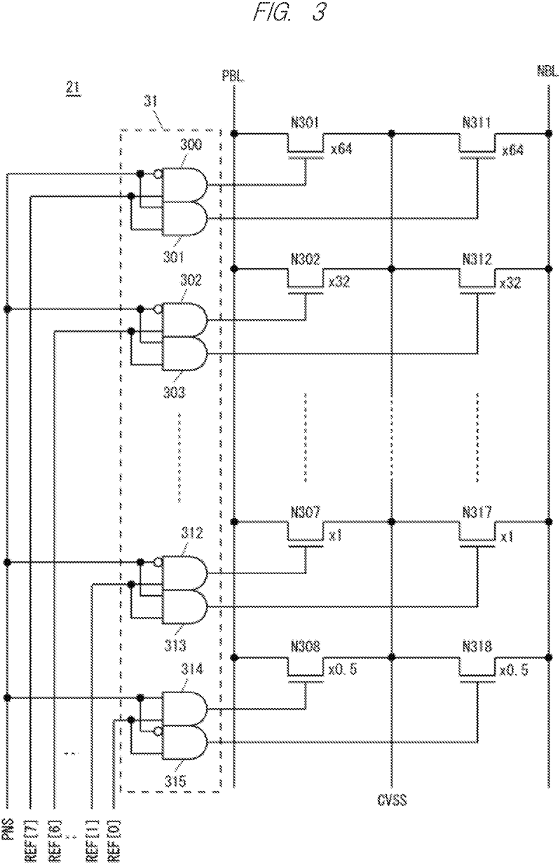

FIG. 3 shows a circuit diagram of the AD conversion REF cell 21 according to the first embodiment. As shown in FIG. 3, the AD conversion REF cell 21 has multiple sets of two transistors connected in series between the data line PBL and the data line NBL. Also, the AD conversion REF cell 21 also has a control logic 31 that controls the transistors connected between the data line PBL and the data line NBL.

The sets of the two transistors connected in series between the data line PBL and the data line NBL have different transistor sizes for each set. FIG. 3 shows an example of the AD conversion REF cell 21 in which the transistor sizes are set to 64, 32, 16, 8, 4, 2, 1, and 0.5. Further, the cell ground wiring CVSS is connected to the nodes where the transistors constituting each transistor set are connected. The control logic 31 has an AND gate with inverting input and an AND gate for each transistor set. Further, a polarity control signal PNS is input to the inverting input terminal of the AND gate with inverting input and one terminal of the AND gate. Also, a signal of a bit corresponding to a transistor set in the reference control signal REF is input to the non-inverting input terminal of the AND gate with inverting input and the other terminal of the AND gate. In the example shown in FIG. 3, the most significant bit of the reference control signal REF is input to the control logic 31 corresponding to the transistor set whose transistor size is 64, and the less significant bit of the reference control signal REF is input as the transistor size becomes smaller. Further, in the AD conversion REF cell 21, the transistor on the side of the data line PBL is controlled by the output of the AND gate with inverting input, and the transistor on the side of the data line NBL is controlled by the output of the AND gate. As for the control logic 31 corresponding to the transistor set whose transistor size is 0.5, the transistor on the side of the data line NBL is controlled by the output of the AND gate with inverting input, and the transistor on the side of the data line PBL is controlled by the output of the AND gate.

Accordingly, in the AD conversion REF cell 21, when the polarity control signal PNS is selecting the side of the data line PBL (for example, at low level), the current is drawn from the data line PBL to the cell ground wiring CVSS by the transistor specified by the reference control signal REF. On the other hand, when the polarity control signal PNS is selecting the side of the data line NBL (for example, at high level), the current is drawn from the data line NBL to the cell ground wiring CVSS by the transistor specified by the reference control signal REF. As for the transistors whose transistor size is set to 0.5 (for example, N308 and N318), the current is drawn to the cell ground wiring CVSS from the data line on the side opposite to that of the other transistors.

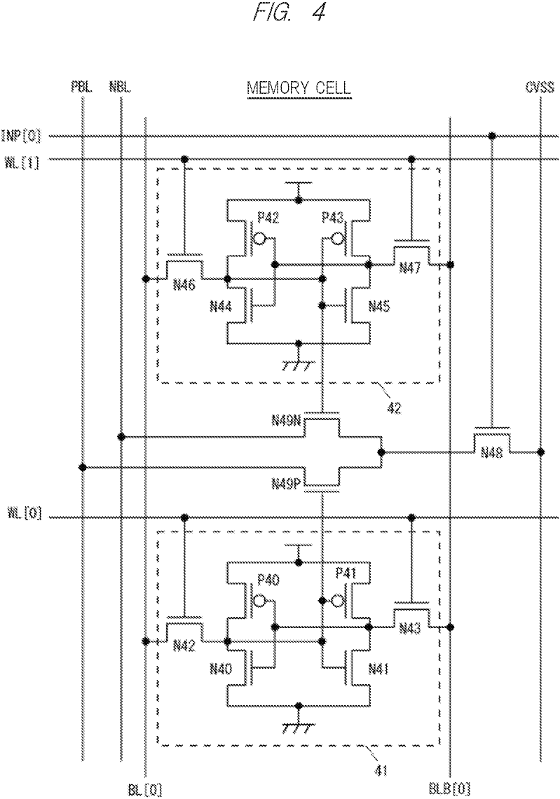

FIG. 4 shows a circuit diagram of the memory cell according to the first embodiment. FIG. 4 shows only one of the plurality of memory cells shown in FIG. 2. As shown in FIG. 4, the memory cell includes a first memory cell 41 and a second memory cell 42. The memory cell further includes NMOS transistors N48, N49P, and N49N. The NMOS transistor N48 has one end connected to the cell ground line CVSS and the other end connected to one ends of the NMOS transistor N49P and the NMOS transistor N49N. Also, the 0-th bit of the input value INP is supplied to a gate of the NMOS transistor N48. The data line PBL is connected to the other end of the NMOS transistor N49P. A gate of the NMOS transistor N49P is connected to the first memory cell 41. The data line NBL is connected to the other end of the NMOS transistor N49N. A gate of the NMOS transistor N49N is connected to the second memory cell 42.

The first memory cell 41 and the second memory cell 42 have a configuration functioning as an SRAM (Static Random Access Memory). Specifically, the first memory cell 41 has PMOS transistors P40 and P41 and NMOS transistors N40 to N43. The PMOS transistor P40 and the NMOS transistor N40 are connected in series between the power supply wiring and the ground wiring, and have gates connected commonly. The PMOS transistor P41 and the NMOS transistor N41 are connected in series between the power supply wiring and the ground wiring, and have gates connected commonly. Also, the gates of the PMOS transistor P40 and the NMOS transistor N40 are connected to a node where the PMOS transistor P41 and the NMOS transistor N41 are connected and to one end of the NMOS transistor N43. Further, the gates of the PMOS transistor P41 and the NMOS transistor N41 are connected to a node where the PMOS transistor P40 and the NMOS transistor N40 are connected and to one end of the NMOS transistor N42. The other end of the NMOS transistor N42 is connected to a complementary bit line BL. The other end of the NMOS transistor N43 is connected to a complementary bit line BLB. Also, a word line WL[0] is connected to gates of the NMOS transistors N42 and N43.

Further, the second memory cell 42 has PMOS transistors P42 and P43 and NMOS transistors N44 to N47. The PMOS transistor P42 and the NMOS transistor N44 are connected in series between the power supply wiring and the ground wiring, and have gates connected commonly. The PMOS transistor P43 and the NMOS transistor N45 are connected in series between the power supply wiring and the ground wiring, and have gates connected commonly. Also, the gates of the PMOS transistor P42 and the NMOS transistor N44 are connected to a node where the PMOS transistor P43 and the NMOS transistor N45 are connected and to one end of the NMOS transistor N47. Further, the gates of the PMOS transistor P43 and the NMOS transistor N45 are connected to a node where the PMOS transistor P42 and the NMOS transistor N45 are connected and to one end of the NMOS transistor N46. The other end of the NMOS transistor N46 is connected to the complementary bit line BL. The other end of the NMOS transistor N47 is connected to the complementary bit line BLB. Also, a word line WL[1] is connected to gates of the NMOS transistors N46 and N47.

In the memory cell, a value is written by fixing the state of an inverter in the first memory cell 41 by the complementary bit lines BL and BLB in a state where the word line WL[0] is at the high level. Also, in the memory cell, a value is written by fixing the state of an inverter in the second memory cell 42 by the complementary bit lines BL and BLB in a state where the word line WL[1] is at the high level.

Also, in the memory cell, the open/close state of the NMOS transistor N49P is controlled by the value held by the inverter composed of the PMOS transistor P40 and the NMOS transistor N40. Further, in the memory cell, the open/close state of the NMOS transistor N49N is controlled by the value held by the inverter composed of the PMOS transistor P42 and the NMOS transistor N44.

In the memory cell shown in FIG. 4, the memory cell is construed as storing a logical value “0” when both the first memory cell 41 and the second memory cell 42 store a logical value “0”. Also, the memory cell is construed as storing a logical value “+1” when the first memory cell 41 stores a logical value “1” and the second memory cell 42 store a logical value “0”. Further, the memory cell is construed as storing a logical value “-1” when the first memory cell 41 stores a logical value “0” and the second memory cell 42 store a logical value “1”.

Accordingly, when the logical value “0” is stored in the memory cell, both the NMOS transistor N49P and the NMOS transistor N49N are turned off, and no current flows from the data lines PBL and NBL to the constant current source 14 even if the input value INP is the logical value “1”.

On the other hand, when the logical value “+1” is stored in the memory cell, the NMOS transistor N49P is turned on and the NMOS transistor N49N is turned off. At this time, if the input value INP is the logical value “1”, a current flows from the data line PBL to the constant current source 14 via the NMOS transistors N49P and N48 which are in the ON state, and the voltage of the data line PBL is lowered. At this time, the voltage of the data line NBL is not lowered. On the other hand, if the input value INP is the logical value “0” at this time, the NMOS transistor N48 is turned off, so that no current flows from the data lines PBL and NBL to the constant current source 14, and the voltage of the data lines PBL and NBL is not lowered.

Furthermore, when the logical value “-1” is stored in the memory cell, the NMOS transistor N49N is turned on and the NMOS transistor N49P is turned off. At this time, if the input value INP is a logical value “1”, a current flows from the data line NBL to the constant current source 14 via the NMOS transistors N49N and N48 which are in the ON state, and the voltage of the data line NBL is lowered and the voltage of the data line PBL is not lowered. On the other hand, if the input value INP is a logical value “0” at this time, the NMOS transistor N48 is turned off, so that no current flows from the data lines PBL and NBL to the constant current source 14, and the voltage of the data lines PBL and NBL is not lowered.

Namely, in the memory cell, the first memory cell 41 can be regarded as being used to store the logical value “+1” in the memory cell, and the second memory cell 42 can be regarded as being used to store the logical value “-1” in the memory cell.

Consequently, the product operation is performed between the ternary value stored in the memory cell and the input value INP. Namely, the six states of 0×0, 0×(+1), 0×(-1), 1×0, 1×(+1), and 1×(-1) are formed according to the logical value of the input value and the logical value of the memory cell. In this case, a product operation is performed between the logical value of the input value and the logical value stored in the memory cell, and when the result of the product operation is a logical value “1”, a current flows between the data line PBL and the constant current source 14 and the voltage of the data line PBL is lowered. On the other hand, when the result of the product operation is a logical value “-1”, a current flows between the data line NBL and the constant current source 14 and the voltage of the data line NBL is lowered.

Further, in the memory cell of the semiconductor device 1, the currents according to results of the product operation of the plurality of memory cells connected to the data line are superimposed on each of the data lines PBL and NBL, and the current and voltage are determined on each of the data lines PBL and NBL. Namely, the sum operation is performed such that the products obtained in the plurality of memory cells are summed on the data lines PBL and NBL. The result of the product-sum operation, which is the result of the sum operation, is output via the data lines PBL and NBL.

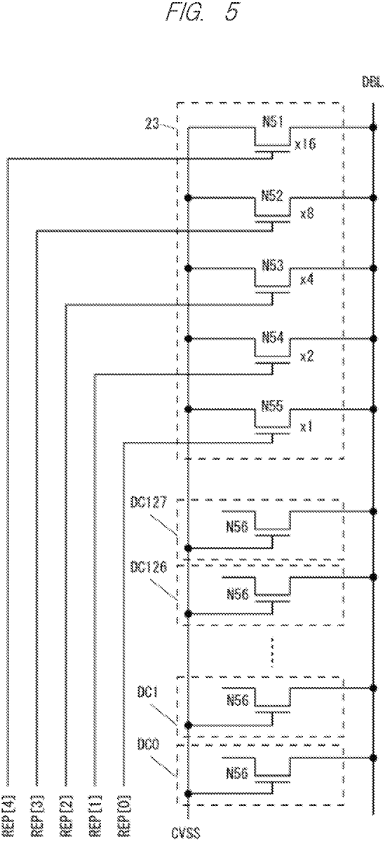

Next, the replica cell 23 and the dummy cells will be described. FIG. 5 shows a circuit diagram of the replica cell and the dummy cells according to the first embodiment. First, the replica cell 23 has replica transistors provided between the constant current source 14 and the data line DBL, and the replica transistor changes either the logical transistor size or the connection time between the constant current source 14 and the data line DBL according to the magnitude of the set value REP. The example in FIG. 5 shows the replica cell 23 that changes the logical transistor size according to the magnitude of the set value. As shown in FIG. 5, the replica cell 23 has NMOS transistors N51 to N55 with different transistor sizes as the replica transistors. In the example shown in FIG. 5, the NMOS transistor N51 is set to have a transistor size of 16, the NMOS transistor N52 is set to have a transistor size of 8, the NMOS transistor N52 is set to have a transistor size of 4, the NMOS transistor N54 is set to have a transistor size of 2, and the NMOS transistor N55 is set to have a transistor size of 1. Further, the NMOS transistors N51 to N55 have one ends connected to the data line DBL and the other ends connected to the cell ground wiring CVSS. Further, in the example shown in FIG. 5, the set value REP is composed of 5 bits. Also, the most significant bit of the set value REP is input to a gate of the NMOS transistor N51, the fourth bit of the set value REP is input to a gate of the NMOS transistor N52, the third bit of the set value REP is input to a gate of the NMOS transistor N53, the second bit of the set value REP is input to a gate of the NMOS transistor N54, and the least significant bit of the set value REP is input to a gate of the NMOS transistor N55.

In other words, the replica cell 23 turns on at least one of the NMOS transistors N51 to N55 according to the set value REP with a logical value “1” to draw a current from the data line DBL to the cell ground wiring CVSS with a current value corresponding to the transistor size, thereby lowering the voltage of the data line DBL.

Each of the dummy cells has an NMOS transistor N56. The NMOS transistor N56 has one end connected to the data line DBL and the other end left open. A gate of the NMOS transistor N56 is connected to the cell ground line CVSS. Thus, the dummy cell spuriously produces, to the data line DBL, the parasitic capacitance that the NMOS transistor N49N of the memory cell supplies to the data line NBL or the parasitic capacitance that the NMOS transistor N49P supplies to the data line PBL.

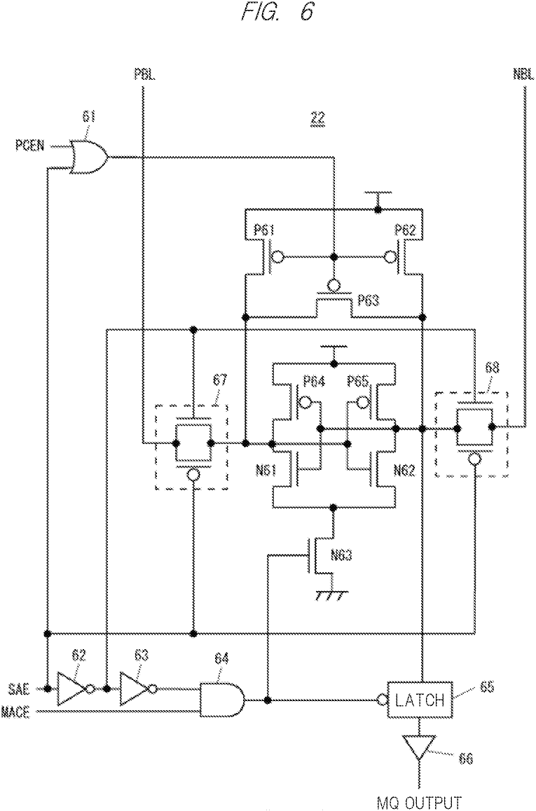

Next, the first determination circuit 22 will be described in detail. FIG. 6 shows a circuit diagram of the first determination circuit 22 according to the first embodiment. As shown in FIG. 6, the first determination circuit 22 has PMOS transistors P61 to P65, NMOS transistors N61 to N63, an OR gate 61, inverters 62 and 63, an AND gate 64, a latch 65, a buffer 66, and transfer gates 67 and 68.

The PMOS transistors P61 and P62 have sources connected to the power supply wiring and drains coupled by the PMOS transistor P63. Also, the drain of the PMOS transistor P61 is connected to a node where the PMOS transistor P64 and the NMOS transistor N61 are connected. The drain of the PMOS transistor P62 is connected to a node where the PMOS transistor P65 and the NMOS transistor N62 are connected. A control signal is supplied from the OR gate 61 to gates of the PMOS transistors P61 to P63. The OR gate 61 outputs the logical sum of the power supply control enable signal PCEN and the sense amplifier enable signal SAE. Namely, when at least one of the power supply control enable signal PCEN and the sense amplifier enable signal SAE is at the high level, the PMOS transistors P61 to P63 are turned off. On the other hand, when both the power supply control enable signal PCEN and the sense amplifier enable signal SAE are at the low level, the PMOS transistors P61 to P63 are turned on.

The PMOS transistor P64 and the NMOS transistor N61 are connected in series between the power supply wiring and a drain of the NMOS transistor N63, and have gates connected commonly. The PMOS transistor P65 and the NMOS transistor N62 are connected in series between the power supply wiring and the drain of the NMOS transistor N63, and have gates connected commonly. Also, the gates of the PMOS transistor P64 and the NMOS transistor N61 are connected to the node where the PMOS transistor P65 and the NMOS transistor N62 are connected, and are connected to the data line NBL via the transfer gate 68. Further, the gates of the PMOS transistor P65 and the NMOS transistor N62 are connected to the node where the PMOS transistor P64 and the NMOS transistor N61 are connected, and are connected to the data line PBL via the transfer gate 67. In other words, the PMOS transistors P64 and P65 and the NMOS transistors N61 to N63 form a latch-type sense amplifier structure using the NMOS transistor N63 as a current source.

The transfer gates 67 and 68 are turned on when the sense amplifier enable signal SAE becomes the low level, and turned off when the sense amplifier enable signal SAE becomes the high level.

The AND gate 64 outputs the logical product of the sense amplifier enable signal SAE and the product-sum operation mode enable signal MACE. In the first determination circuit 22, when both the sense amplifier enable signal SAE and the product-sum operation mode enable signal MACE are at the high level, the determination cell configured of the PMOS transistors P64 and P65 and the NMOS transistors N61 and N62 is operated by the NMOS transistor N63. Also, the latch 65 becomes an input passing state at the rising edge of the output of the AND gate 64, transmits the logical value of the connection node between the PMOS transistor P65 and the NMOS transistor N62 to the buffer 66, and takes in the logical value at the falling edge.

Namely, the first determination circuit 22 resets the determination cell during the period when either the power supply control enable signal PCEN or the sense amplifier enable signal SAE is at the low level. Then, the first determination circuit 22 sets the sense amplifier enable signal SAE and the product-sum operation mode enable signal MACE to the high level in the state where both the power supply control enable signal PCEN and the sense amplifier enable signal SAE are at the high level, whereby the determination cell compares the magnitude of potentials of the data line PBL and the data line NBL. Thereafter, the first determination circuit 22 outputs the comparison result to the interface controller 16 as an MQ output from the buffer 66 via the latch 65 which is in the input passing state.

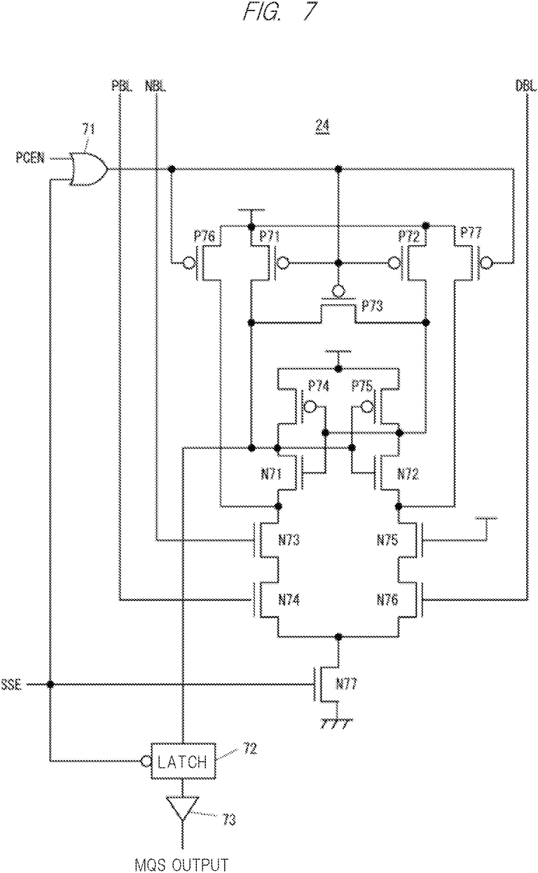

Next, the second determination circuit 24 will be described in detail. FIG. 7 shows a circuit diagram of the second determination circuit 24 according to the first embodiment. As shown in FIG. 7, the second determination circuit 24 has PMOS transistors P71 to P77, NMOS transistors N71 to N77, an OR gate 71, a latch 72, and a buffer 73.

The PMOS transistors P71 and P72 have sources connected to the power supply wiring and drains coupled by the PMOS transistor P73. Also, the drain of the PMOS transistor P71 is connected to a node where the PMOS transistor P74 and the NMOS transistor N71 are connected. The drain of the PMOS transistor P72 is connected to a node where the PMOS transistor P75 and the NMOS transistor N72 are connected. The PMOS transistors P76 and P77 have sources connected to the power supply wiring. A drain of the PMOS transistor P76 is connected to a node where the NMOS transistor N71 and the NMOS transistor N73 are connected. A drain of the PMOS transistor P77 is connected to a node where the NMOS transistor N72 and the NMOS transistor N75 are connected.

A control signal is supplied from the OR gate 71 to gates of the PMOS transistors P71 to P73, P76, and P77. The OR gate 71 outputs the logical sum of the power supply control enable signal PCEN and the second sense enable signal SSE. Namely, when at least one of the power supply control enable signal PCEN and the second sense enable signal SSE is at the high level, the PMOS transistors P71 to P73, P76, and P77 are turned off. On the other hand, when both the power supply control enable signal PCEN and the second sense enable signal SSE are at the low level, the PMOS transistors P71 to P73, P76, and P77 are turned on.

The PMOS transistor P74, the NMOS transistor N71, the NMOS transistor N73, and the NMOS transistor N74 are connected in series between the power supply wiring and a drain of the NMOS transistor N77 in this order. Also, a gate of the PMOS transistor P74 and a gate of the NMOS transistor N71 are commonly connected. Further, the PMOS transistor P75, the NMOS transistor N72, the NMOS transistor N75, and the NMOS transistor N76 are connected in series between the power supply wiring and the drain of the NMOS transistor N77 in this order. Also, a gate of the PMOS transistor P75 and a gate of the NMOS transistor N72 are commonly connected.

Further, the gates of the PMOS transistor P74 and the NMOS transistor N71 are connected to the node where the PMOS transistor P75 and the NMOS transistor N72 are connected, and are connected to the drain of the PMOS transistor P72. Also, the gates of the PMOS transistor P75 and the NMOS transistor N72 are connected to the node where the PMOS transistor P74 and the NMOS transistor N71 are connected, and are connected to the drain of the PMOS transistor P71. Also, the drain of the PMOS transistor P76 is connected to the node where the NMOS transistor N71 and the NMOS transistor N73 are connected. The drain of the PMOS transistor P77 is connected to the node where the NMOS transistor N72 and the NMOS transistor N75 are connected.

Further, the second sense enable signal SSE is input to a gate of the NMOS transistor N77. The PMOS transistors P74 and P75 and the NMOS transistors N71 to N76 are operated with the NMOS transistor N77 as a current source. Also, the latch 72 passes the logical value of the connection node between the PMOS transistor P74 and the NMOS transistor N71 at the rising edge of the second sense enable signal SSE.

Namely, the second determination circuit 24 resets the determination cell during the period when both the power supply control enable signal PCEN and the second sense enable signal SSE are at the low level. Then, the second determination circuit 24 sets the second sense enable signal SSE to the high level in the state where the power supply control enable signal PCEN is set to the high level, whereby the determination cell performs the comparison of the potential magnitude between the total sum of the memory cells connected to the data line PBL and the memory cells connected to the data line NBL and the number of cells specified by the set value REP. Thereafter, the second determination circuit 24 outputs the comparison result to the interface controller 16 as an MQS output from the buffer 73 via the latch 72 which is in the input passing state by raising the second sense enable signal SSE. In the semiconductor device 1, the interface controller 16 determines whether the product-sum operation mode enable signal MACE is enabled or disabled based on the MQS output.

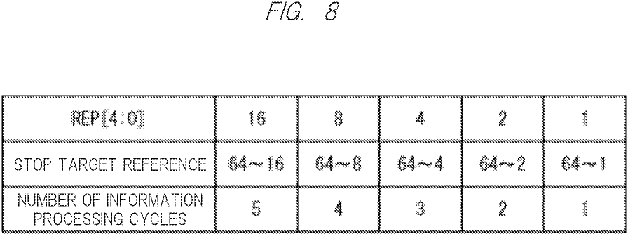

Here, FIG. 8 shows a table for describing a relationship between the set value REP and the number of information processing cycles to be stopped in the semiconductor device 1 according to the first embodiment. As shown in FIG. 8, in the semiconductor device 1 according to the first embodiment, the number of information processing cycles required for AD conversion in accordance with the number of cells which perform the product-sum operation is originally eight including the code determination cycle because of 128 inputs, but when the second determination circuit 24 determines that the number of cells connected to the data lines PBL and NBL is smaller than the number of cells specified by the set value REP output by the interface controller 16, the number of information processing cycles to be performed is determined by the value indicated by the number of information processing cycles associated with the set value REP. In the example shown in FIG. 8, when the NMOS transistor N51 of the replica cell 23 with the transistor size of 16 is specified, the number of information processing cycles can be changed to five by the set value REP. In this case, the information processing cycles performed by using transistors with the transistor size of 64 to 16 in the AD conversion REF cell 21 are stopped (three information cycles are stopped), and five information processing cycles are performed. The number of times of the information processing to be performed decreases as the set value REP decreases.

Assuming that the transistor in the replica cell 23 connected to the data line DBL by the set value REP is the NMOS transistor N51 with the transistor size of 16, the potential from the data line DBL becomes the same as the potential when sixteen cells are connected to the data line PBL or the data line NBL. At this time, if the total sum of the number of memory cells connected to the data line PBL and the number of memory cells connected to the data line NBL is less than 16, it is obvious that the determination value of the information processing cycles when the transistor size of the transistors constituting the AD conversion REF cell 21 is larger than 16 such as 64, 32, and 16 is fixed to 0, and the correct value can be derived without performing calculations for the part where the value is fixed. Therefore, in the semiconductor device 1 according to the first embodiment, the size of the part whose value is fixed is determined by using the data line DBL, the replica cell 23, and the second determination circuit 24, and the current supplied from the constant current source 14 to the memory cells and the AD conversion REF cell 21 is cut off during the period when the information processing is to be performed for the ensured part, thereby reducing the power consumption.

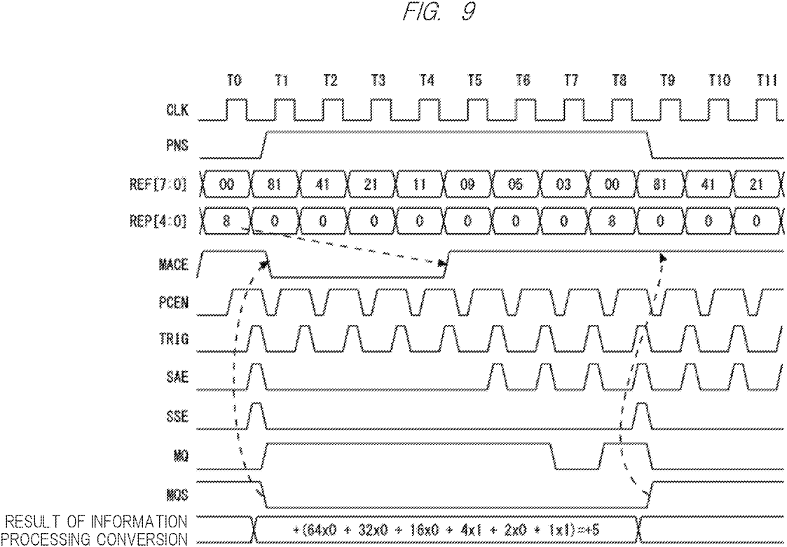

Thus, the operation of the semiconductor device 1 according to the first embodiment will be described. FIG. 9 shows a timing chart for describing the operation of the semiconductor device 1 according to the first embodiment. The example shown in FIG. 9 is an example in which 8 is specified as the set value REP.

As shown in FIG. 9, in the semiconductor device 1, when the period when the interface controller 16 fixes one information processing result of the preset number of bits by the output value of the first determination circuit 22 is defined as one information processing period (period when the information processing result is switched in FIG. 8), the second determination circuit 24 is selectively enabled in the initial information processing cycle of the one information processing period. Specifically, the one information processing period starts at timing T0. Then, the interface controller 16 sets the product-sum operation mode enable signal MACE high to the high level at timing T0. In addition, at timing T0, the least significant bit of the reference control signal REF is 0. Therefore, the sense amplifier enable signal SAE and the second sense enable signal SSE become the high level. Consequently, the first determination circuit 22 and the second determination circuit 24 operate, and the first determination circuit 22 outputs the high level as the MQ output and the second determination circuit 24 outputs the low level as the MQS output in the example shown in FIG. 9. This means that the total number of memory cells connected to the data line PBL and the data line NBL is smaller than 8 in the input value processed during the information processing period starting at timing T0.

Thereafter, at timing T1, the interface controller 16 sets the product-sum operation mode enable signal MACE to the low level such that the sense amplifier enable signal SAE is maintained at the low level over four information processing cycles based on the fact that the MQS output is the low level. Current supply to the AD conversion REF cell 21, the memory cells MC0 to MC127, and the first determination circuit 22 is stopped during the period when the product-sum operation mode enable signal MACE is at the low level. On the other hand, since there is a possibility that conversion is being performed on other data line groups in the cell array 13, the conversion processing cycle itself is not skipped even though the current supply to the AD conversion REF cell 21, the memory cells MC0 to MC127, and the first determination circuit 22 is stopped.

Then, the interface controller 16 switches the product-sum operation mode enable signal MACE to the high level at timing T5. Consequently, the first determination circuit 22 transmits the MQ output based on the product-sum operation result to the interface controller 16 by information processing. Thereafter, a series of information processing results are fixed by the information processing up to T7.

Then, a new information processing cycle is started, and the interface controller 16 sets the product-sum operation mode enable signal MACE to the high level at timing T8 as at timing T0, and the second sense enable signal SSE and the sense amplifier enable signal SAE become the high level because the least significant bit of the reference control signal REF becomes 0. At this time, since the second determination circuit 24 has transmitted the MQS output of the high level to the interface controller 16, the interface controller 16 maintains the product-sum operation mode enable signal MACE at the high level, and information processing is performed over one information processing period from timing T8 to timing T15 (not shown).

As described above, in the semiconductor device 1 according to the first embodiment, attention is focused on the relationship between the number of memory cells connected to the data line PBL and the data line NBL and the bits whose values are fixed without performing information processing, and current supply to the AD conversion REF cell 21 and the memory cells is stopped for the bits whose values are fixed without performing information processing, thereby reducing power consumption.

In addition, in the semiconductor device 1 according to the first embodiment, when more memory cells than the number of memory cells specified by the set value REP are connected to the data lines PBL and NBL, information processing is performed as usual so as to prevent the lack of information processing.

Furthermore, in recent years, the ratio of weight coefficients with a value of 0 among the weight coefficients used in deep learning or the like has decreased, and weights with intermediate values are used in many cases, so that it is requested to set a range in which information processing is stopped according to situation as in the semiconductor device 1. For this reason, in recent years, flexible settings such as those of the semiconductor device 1 are highly effective in reducing power consumption. Further, in deep learning, the weight coefficient tends to decrease as the learning progresses, and a higher power reduction effect can be obtained by applying the semiconductor device 1 to artificial intelligence whose learning has progressed.

In the above embodiment, the set value REP is output by the interface controller 16, but the set value REP may be input from the outside. Also, the set value REP may be specified by the number of information processing cycles to be stopped or the number of information processing cycles to be performed instead of the number of transistors connected to the data line, and may be generated by the conversion processing of converting into the number of transistors in an internal circuit such as the interface controller 16.

### Second Embodiment

In the second embodiment, an example of dynamically changing the set value REP will be described. The set value REP can be changed by, for example, the interface controller 16. Note that the set value REP may be changed outside the semiconductor device 1.

Thus, in the second embodiment, the interface controller 16 reduces the stop set value when the enabling rate of the stop command signal (for example, MQS output) exceeds a preset first threshold, and increases the set value when the enabling rate of the MQS output falls below a second threshold that is smaller than the first threshold.

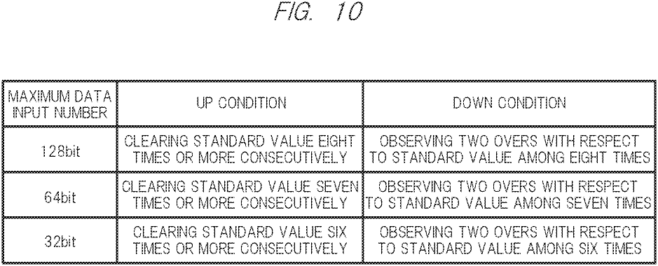

Here, FIG. 10 shows a table for describing changing conditions of the set value in the semiconductor device according to the second embodiment. Note that the table shown in FIG. 10 shows an example, and the condition setting method can be arbitrarily set according to the specifications of the semiconductor device.

In the example shown in FIG. 10, three conditions are presented for each maximum data number (number of bits) of the input value. In FIG. 10, as an UP condition in the case where the input value INP has the data number of 128 bits, the condition that the number of transistors determined by the current set value REP is cleared eight times consecutively (namely, the determination that the MQS output is the high level continues eight times) is defined, and the magnitude of the set value REP is reduced by one when the condition is satisfied. On the other hand, as a DOWN condition in the case where the input value INP has the data number of 128 bits, the condition that the two overs are observed with respect to the number of transistors determined by the current set value REP among the eight determinations (namely, the MQS output is determined to the low level twice among eight times) is defined, and the magnitude of the set value REP is increased by one when the condition is satisfied.

Also, in the example shown in FIG. 10, as an UP condition in the case where the input value INP has the data number of 64 bits, the condition that the number of transistors determined by the current set value REP is cleared seven times consecutively (namely, the determination that the MQS output is the high level continues seven times) is defined, and the magnitude of the set value REP is reduced by one when the condition is satisfied. On the other hand, as a DOWN condition in the case where the input value INP has the data number of 64 bits, the condition that the two overs are observed with respect to the number of transistors determined by the current set value REP among the seven determinations (namely, the MQS output is determined to the low level twice among seven times) is defined, and the magnitude of the set value REP is increased by one when the condition is satisfied.

Further, in the example shown in FIG. 10, as an UP condition in the case where the input value INP has the data number of 32 bits, the condition that the number of transistors determined by the current set value REP is cleared six times consecutively (namely, the determination that the MQS output is the high level continues six times) is defined, and the magnitude of the set value REP is reduced by one when the condition is satisfied. On the other hand, as a DOWN condition in the case where the input value INP has the data number of 32 bits, the condition that the two overs are observed with respect to the number of transistors determined by the current set value REP among the six determinations (namely, the MQS output is determined to the low level twice among six times) is defined, and the magnitude of the set value REP is increased by one when the condition is satisfied.

In this way, by dynamically changing the set value REP, even when the result of the product-sum operation increases or decreases in deep learning or the like, the appropriate number of information processing cycle skips can be set, and it is possible to reduce the power consumption more than that in the semiconductor device 1 according to the first embodiment.

### Third Embodiment

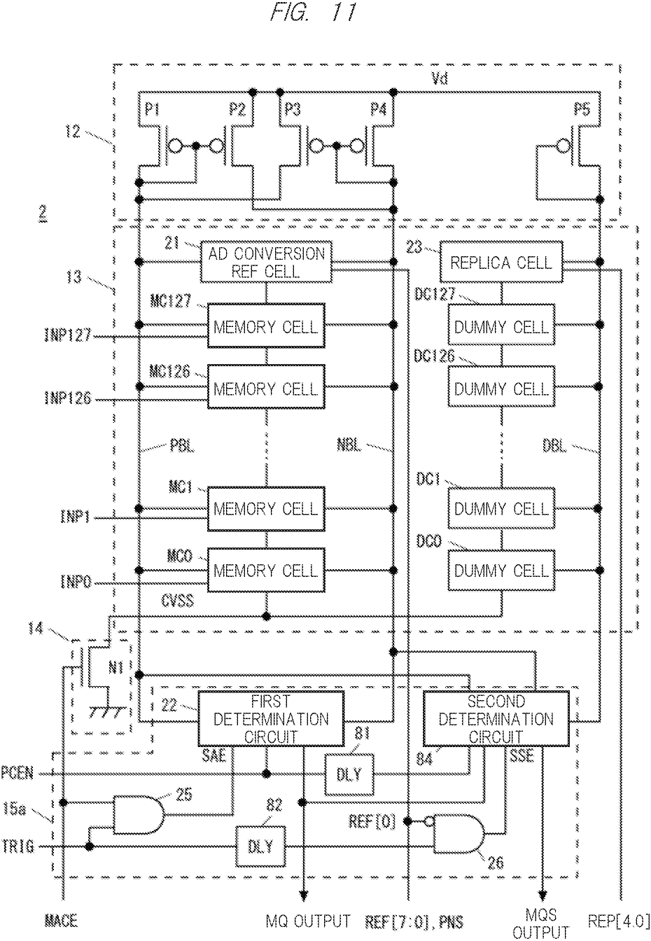

In the third embodiment, a semiconductor device 2 which is another form of the semiconductor device 1 according to the first embodiment will be described. FIG. 11 shows a detailed block diagram of a configuration around memory cells of the semiconductor device according to the third embodiment.

As shown in FIG. 11, the semiconductor device 2 has a determination circuit 15a instead of the determination circuit 15. The determination circuit 15a is obtained by adding delay circuits 81 and 82 to the determination circuit 15 and replacing the second determination circuit 24 with a second determination circuit 84.

The delay circuit 81 delays the arrival time of the power supply control enable signal PCEN at the second determination circuit 84 more than that at the first determination circuit 22. The delay circuit 82 delays the arrival time of the trigger signal TRIG at the second determination circuit 84 more than that at the first determination circuit 22. Namely, in the semiconductor device 2, the second determination circuit 84 operates later in time than the first determination circuit 22.

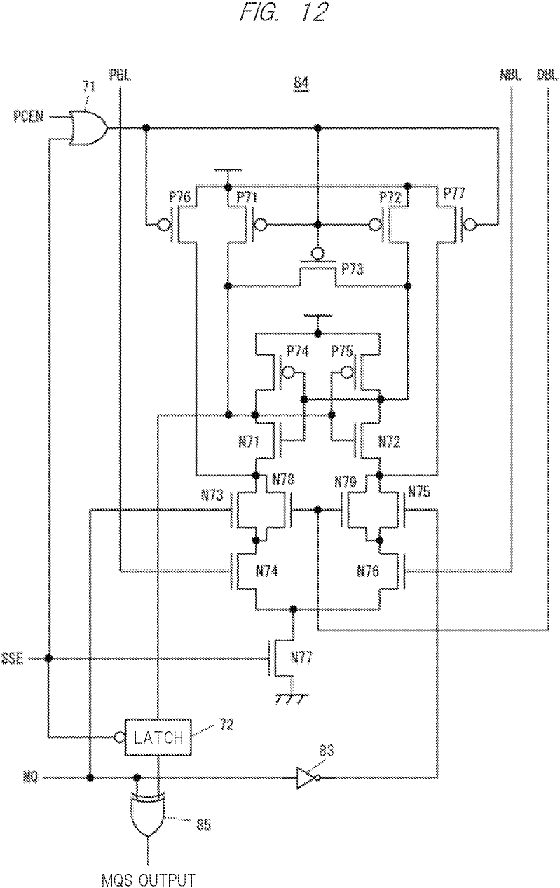

The second determination circuit 84 enables the MQS output when the difference between the number of memory cells connected to the data line PBL and the number of memory cells connected to the data line NBL is smaller than a comparison value derived from the set value REP. FIG. 12 shows a circuit diagram of the second determination circuit 84 according to the third embodiment.

As shown in FIG. 12, the second determination circuit 84 is obtained by adding NMOS transistors N78 and N79, an inverter 83, and an EXOR gate 85 to the second determination circuit 24. Also, the wiring of the second determination circuit 84 is changed from that of the second determination circuit 24.

Specifically, the NMOS transistor N78 is connected in parallel with the NMOS transistor N73, and the NMOS transistor N79 is connected in parallel with the NMOS transistor N75. Also, the output of the latch 72 is output by the EXOR gate 85 as an exclusive OR with the MQ output.

In the second determination circuit 84, the MQ output is supplied to a gate of the NMOS transistor N73. An inverted value of the MQ output is supplied to a gate of the NMOS transistor N75. The data line DBL is connected to gates of the NMOS transistors N78 and N79. The data line PBL is connected to a gate of the NMOS transistor N74. The data line NBL is connected to a gate of the NMOS transistor N76.

The second determination circuit 84 starts operating with a delay from the first determination circuit 22 in order to wait for the MQ output to be fixed. Then, in the second determination circuit 84, when the MQ output is at the high level, that is, when the number of memory cells connected to the data line PBL is larger than the number of memory cells connected to the data line NBL, the signal of the high level is input to the gate of the NMOS transistor N73 and the signal of the low level is input to the gate of the NMOS transistor N75. Consequently, the NMOS transistor N78 is disabled, while the NMOS transistor N79 is brought into the state where a current corresponding to the voltage of the data line DBL flows.

With this operation, the sum of the number of memory cells connected to the data line having the smaller number of connected memory cells and the number of memory cells specified by the set value REP is compared with the number of memory cells connected to the data line having the larger number of connected memory cells. Namely, the second determination circuit 84 enables the MQS output when the difference between the number of memory cells connected to the data line PBL and the number of memory cells connected to the data line NBL is smaller than the comparison value derived from the set value REP.

In the semiconductor device 1 according to the first embodiment, for example, the sum of the number of memory cells connected to the data line PBL and the number of memory cells connected to the data line NBL is compared with the number of memory cells indicated by the set value REP. Therefore, when the number of memory cells connected to the data line PBL is 5 and the number of memory cells connected to the data line NBL is 4, the total value is 9, and thus six information processing cycles are required.

On the other hand, in the second determination circuit 84 according to the third embodiment, when the number of memory cells connected to the data line PBL is 5 and the number of memory cells connected to the data line NBL is 4, the difference is 1, and thus only two information processing cycles are required in the third embodiment.

In other words, the number of information processing cycles that must be performed can be reduced by using the second determination circuit 84 according to the third embodiment, and it is thus possible to further suppress the power consumption.

### Fourth Embodiment

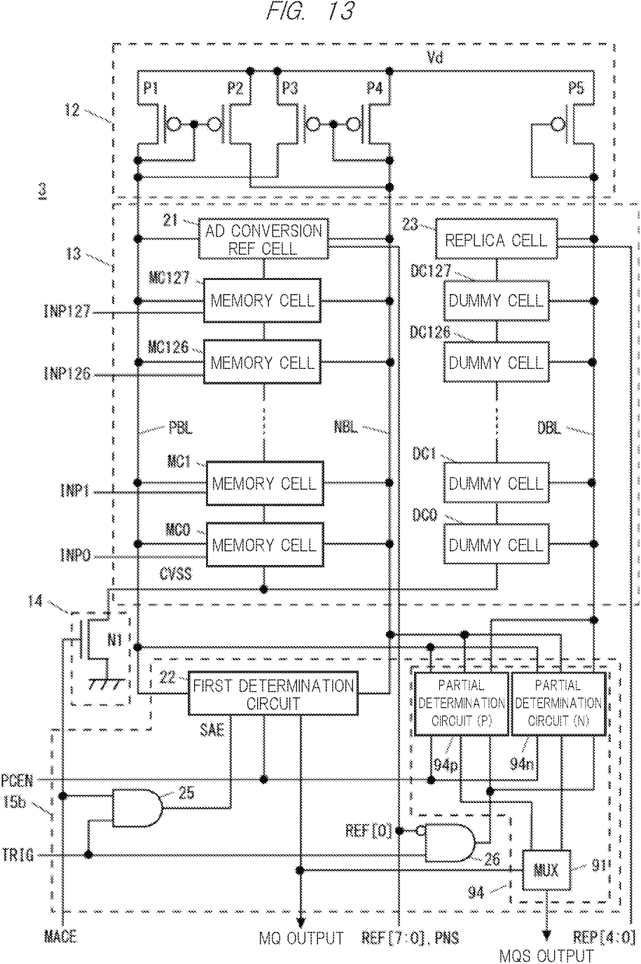

In the fourth embodiment, a semiconductor device 3 which is another form of the semiconductor device 1 according to the first embodiment will be described. FIG. 13 shows a detailed block diagram of a configuration around memory cells of the semiconductor device according to the fourth embodiment.

As shown in FIG. 13, the semiconductor device 3 has a determination circuit 15b instead of the determination circuit 15. The determination circuit 15b is obtained by replacing the second determination circuit 24 of the determination circuit 15 with a second determination circuit 94. The second determination circuit 94 has a first partial determination circuit (for example, first partial determination circuit 94p), a second partial determination circuit (for example, second partial determination circuit 94n), and a selection circuit 91.

The first partial determination circuit 94p enables a first partial determination signal when the number of memory cells connected to the data line PBL is smaller than the sum of the comparison value and the number of memory cells connected to the data line NBL. The second partial determination circuit 94n enables a second partial determination signal when the number of memory cells connected to the data line NBL is smaller than the sum of the comparison value and the number of memory cells connected to the data line PBL. The selection circuit 91 selects the first partial determination signal or the second partial determination signal determined to have the larger number of memory cells connected to the data line by the first determination circuit and outputs it as the MQS output.

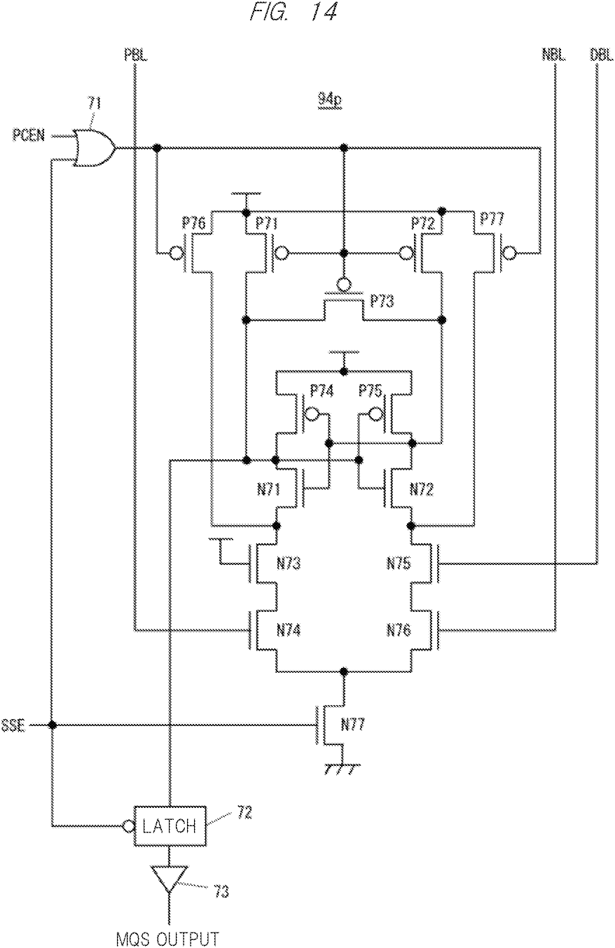

FIG. 14 shows a circuit diagram of the first partial determination circuit 94p according to the fourth embodiment. As shown in FIG. 14, the first partial determination circuit 94p is obtained by changing the wiring connection of the second determination circuit 24. In the first partial determination circuit 94p, the power supply wiring is connected to the gate of the NMOS transistor N73. The data line PBL is connected to the gate of the NMOS transistor N74. The data line DBL is connected to the gate of the NMOS transistor N75. The data line NBL is connected to the gate of the NMOS transistor N76. With this connection, in the first partial determination circuit 94p, the first partial determination signal is enabled when the number of memory cells connected to the data line PBL is smaller than the sum of the comparison value and the number of memory cells connected to the data line NBL.

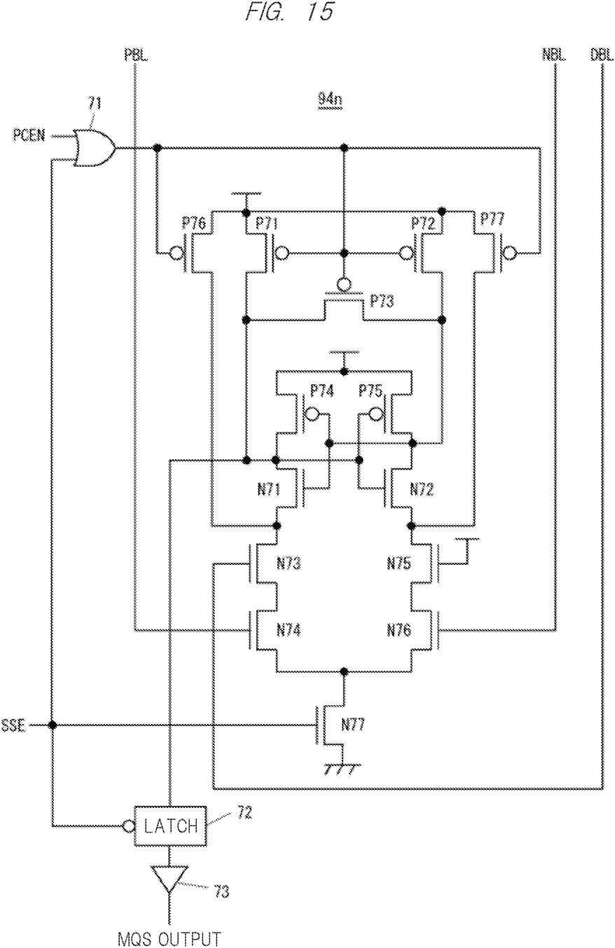

FIG. 15 shows a circuit diagram of the second partial determination circuit 94n according to the fourth embodiment. As shown in FIG. 15, the second partial determination circuit 94n is obtained by changing the wiring connection of the second determination circuit 24. In the second partial determination circuit 94n, the data line DBL is connected to the gate of the NMOS transistor N73. The data line PBL is connected to the gate of the NMOS transistor N74. The power supply wiring is connected to the gate of the NMOS transistor N75. The data line NBL is connected to the gate of the NMOS transistor N76. With this connection, in the second partial determination circuit 94n, the second partial determination signal is enabled when the number of memory cells connected to the data line NBL is smaller than the sum of the comparison value and the number of memory cells connected to the data line PBL.

In the third embodiment, it is necessary to wait for the MQ output of the first determination circuit 22. However, in the second determination circuit 94 according to the fourth embodiment, the first partial determination circuit 94p and the second partial determination circuit 94n respectively determine whether the difference between the number of memory cells connected to the data line PBL and the number of memory cells connected to the data line NBL is larger or smaller than the value specified by the set value REP, and the result after the determination is selected according to the MQ output. Therefore, in the fourth embodiment, it is not necessary to provide the delay as in the third embodiment.

In the foregoing, the invention made by the inventors of this application has been specifically described based on the embodiments, but it is needless to say that the present invention is not limited to the embodiments described above and can be modified in various ways within the scope not departing from the gist thereof.

What is claimed is:

1. A semiconductor device comprising:
a plurality of memory cells configured to output a product of an input value and a held value represented by a ternary value;
a first data line to which the memory cell outputting a first value among the plurality of memory cells is electrically connected;
a second data line to which the memory cell outputting a second value among the plurality of memory cells is electrically connected;
an information processing reference cell configured to supply a reference value, whose value changes for each information processing cycle, to either the first data line or the second data line;
a constant current source configured to generate a drive current with which the plurality of memory cells and the information processing reference cell drive the first data line and the second data line;
a first determination circuit configured to output a binary signal indicating a different value according to a magnitude relationship between the number of the memory cells connected to the first data line and the number of the memory cells connected to the second data line for each information processing cycle;
a third data line;
a replica cell configured to output a comparison value indicating the number of the memory cells connected to at least one of the first data line and the second data line to the third line according to a specified set value;
a second determination circuit configured to enable a stop command signal when at least one of the number of the memory cells connected to the first data line and the number of the memory cells connected to the second data line is smaller than the comparison value; and
a control circuit configured to output the set value and control the constant current source to stop current output until the number of information processing cycles corresponding to the set value has elapsed, in response to the stop command signal indicating an enabled state.

2. The semiconductor device according to claim 1,
wherein each of the plurality of memory cells includes:
a first memory cell configured to electrically connect the first data line to the constant current source when the first value is held; and
a second memory cell configured to electrically connect the second data line to the constant current source when the second value is held, and
wherein a third value is represented when the first memory cell electrically disconnects the first data line and the constant current source and the second memory cell electrically disconnects the second data line and the constant current source.

3. The semiconductor device according to claim 1,
wherein, when a period when an information processing result of one of the number of bits set in advance by an output value of the first determination circuit is fixed is defined as one information processing period, the control circuit selectively enables the second determination circuit in an initial information processing cycle of the one information processing period.

4. The semiconductor device according to claim 1,
wherein the replica cell includes a replica transistor provided between the constant current source and the third data line, and the replica transistor changes either a logical transistor size or a time for connecting the constant current source and the third data line according to a magnitude of the set value.

5. The semiconductor device according to claim 1 further comprising a dummy cell connected to the third data line and configured to spuriously produce a parasitic capacitance which the memory cell supplies to the first data line or the second data line.

6. The semiconductor device according to claim 1,
wherein the second determination circuit enables the stop command signal when a total value of the number of the memory cells connected to the first data line and the number of the memory cells connected to the second data line is smaller than the comparison value.

7. The semiconductor device according to claim 1,
wherein the second determination circuit enables the stop command signal when a difference between the number of the memory cells connected to the first data line and the number of the memory cells connected to the second data line is smaller than the comparison value.

8. The semiconductor device according to claim 1,
wherein the second determination circuit includes:
a first partial determination circuit configured to enable a first partial determination signal when the number of the memory cells connected to the first data line is smaller than a sum of the comparison value and the number of the memory cells connected to the second data line;
a second partial determination circuit configured to enable a second partial determination signal when the number of the memory cells connected to the second data line is smaller than a sum of the comparison value and the number of the memory cells connected to the first data line; and
a selection circuit configured to select the first partial determination signal or the second partial determination signal determined to have a larger number of the memory cells connected to the data line by the first determination circuit and output it as the stop command signal.

9. The semiconductor device according to claim 1,
wherein the control circuit reduces the set value when an enabling rate of the stop command signal exceeds a preset first threshold, and increases the set value when the enabling rate of the stop command signal falls below a preset second threshold smaller than the first threshold.

10. The semiconductor device according to claim 1,
wherein the first data line, the second data line, and the third data line constitute one data line group, and a plurality of the data line groups is provided.
